(19) United States
(12) Patent Application Publication
(10) Pub. No.: US 2026/0212926 A1
(43) Pub. Date: Jul. 23, 2026

(54) CHARGE-DOMAIN SENSING ARCHITECTURES FOR CONTENT-ADDRESSABLE MEMORY

(71) Applicant: University of Notre Dame du Lac, South Bend, IN (US)

(72) Inventors: Kai Ni, Notre Dame, IN (US); Michael Niemier, Notre Dame, IN (US); Jiahui Duan, Notre Dame, IN (US)

(21) Appl. No.: 19/449,774

(22) Filed: Jan. 15, 2026

Related U.S. Application Data
(60) Provisional application No. 63/746,320, filed on Jan. 17, 2025.

(51) Int. Cl. G11C 15/04; G11C 11/22

(52) U.S. Cl. CPC G11C 15/043; G11C 11/2259; G11C 11/2273

(57) ABSTRACT

A content-addressable memory architecture includes memory cells each having a programmable switching device and at least one capacitor, with stored data represented by stored states of the programmable switching devices. During a search operation, search signals are applied to control terminals of the programmable switching devices to conditionally enable charge transfer between the capacitors and a match line based on correspondence between the stored states and the search signals. Following the charge transfer, the match line is placed in a floating condition to permit intentional charge redistribution associated with the memory cells. A correspondence between stored data and a query is determined by sensing a charge-related characteristic of the match line resulting from the charge redistribution, independent of a magnitude of current conducted by the programmable switching devices. The architecture supports ternary content-addressable operations and charge-domain determination of match and mismatch conditions.

### GOVERNMENT SUPPORT CLAUSE

This invention was made with government support under grants CCF2347024 and ECCS2346953 awarded by the National Science Foundation (NSF) and Grant No. HR0011-23-3-0002 awarded by the Defense Advanced Research Projects Agency (DARPA). The government has certain rights in the invention.

### CROSS REFERENCE TO RELATED APPLICATIONS

The present application claims priority benefit to U.S. Provisional Application No. 63/746,320, entitled “CHARGE DOMAIN FERROELECTRIC TERNARY CONTENT-ADDRESSABLE MEMORY,” filed January 17, 2025, which is hereby incorporated herein by reference in its entirety. Any and all applications for which a foreign or domestic priority claim is identified in the Application Data Sheet as filed with the present application are incorporated by reference under 37 CFR 1.57 and made a part of this specification.

### FIELD

The present disclosure relates generally to memory devices and computing architectures, and more particularly to content-addressable memory (CAM) systems, including ternary content-addressable memory (TCAM), employing charge-based sensing techniques.

### BACKGROUND

Content-addressable memory (CAM) is a class of memory in which stored data is accessed by comparison rather than by address. In a CAM system, an input query is compared in parallel against multiple stored entries, and match results are generated based on the correspondence between the query and the stored data. CAM architectures are commonly used in applications such as networking, pattern matching, cache control, and data lookup operations.

Ternary content-addressable memory (TCAM) extends CAM functionality by supporting three logical states, typically representing logic “0,” logic “1,” and a “don’t care” state. The inclusion of a “don’t care” state enables flexible matching operations and is commonly used in applications such as routing tables and classification engines. TCAM implementations typically include memory cells coupled to search lines and match lines, along with sensing circuitry used to evaluate match conditions.

Many TCAM implementations are based on volatile memory technologies, such as static random-access memory (SRAM), combined with comparison circuitry. These architectures generally rely on current flow or voltage levels on match lines to indicate match or mismatch conditions during a search operation. Other TCAM designs incorporate non-volatile memory elements, including programmable switching devices that store information in different electrical states.

In current-based TCAM architectures, the result of a search operation is often determined by measuring current conducted through memory cells or along match lines in response to applied search signals. The sensed electrical response depends on device characteristics, operating conditions, and circuit configurations. In some implementations, multiple memory cells contribute simultaneously to a match line signal, which is evaluated by sensing circuitry to determine a search result.

Various memory cell structures and sensing techniques have been described for CAM and TCAM systems, including designs that support multi-level or ternary storage. These systems may employ capacitive elements, switching devices, or combinations thereof, and may use precharge, evaluation, or discharge phases during operation. The specific mechanisms used to store data, apply search signals, and sense match conditions vary across different CAM and TCAM architectures.

### SUMMARY

The following disclosure describes non-limiting examples of certain embodiments. It should be understood that the described embodiments are provided for purposes of illustration, and that other embodiments may be implemented without departing from the scope of the disclosure.

In some instances, embodiments of the disclosed systems and methods may include fewer than all of the features described herein, or may include additional features not expressly described. Any advantages, benefits, or features described in connection with particular embodiments are not necessarily applicable to all embodiments and should not be construed as limiting the disclosure. Each disclosed embodiment may include multiple aspects, no single aspect of which is solely responsible for the disclosed functionality or characteristics.

Some aspects of the present disclosure relate to a content-addressable memory architecture includes memory cells each having a programmable switching device and at least one capacitor, with stored data represented by stored states of the programmable switching devices. During a search operation, search signals are applied to control terminals of the programmable switching devices to conditionally enable charge transfer between the capacitors and a match line based on correspondence between the stored states and the search signals. Following the charge transfer, the match line is placed in a floating condition to permit intentional charge redistribution associated with the memory cells. A correspondence between stored data and a query is determined by sensing a charge-related characteristic of the match line resulting from the charge redistribution, independent of a magnitude of current conducted by the programmable switching devices. The architecture supports ternary content-addressable operations and charge-domain determination of match and mismatch conditions.

Some aspects of the present disclosure relate to a ternary content-addressable memory architecture based on one ferroelectric field-effect transistor one capacitor (“1FeFET-1C”) configuration, in which each memory cell includes a single ferroelectric field-effect transistor electrically coupled to a single capacitor. The ferroelectric field-effect transistor is programmable to multiple stored states corresponding to ternary data values and operates as a switching element during a search operation. Charge transfer between the capacitor and a match line is conditionally enabled based on stored state and applied search signals, after which the match line is placed in a floating condition to permit intentional charge redistribution. Match or mismatch conditions are determined by sensing a charge-related characteristic of the match line resulting from the charge redistribution, independent of a magnitude of current conducted by the ferroelectric field-effect transistor.

Some aspects of the present disclosure relate to a ternary content-addressable memory architecture based on a two ferroelectric field-effect transistor two capacitor (“2FeFET-2C”) configuration, in which each memory cell includes two ferroelectric field-effect transistors and two capacitors. Ternary data states are represented by combinations of threshold voltage states of the two ferroelectric field-effect transistors. During a search operation, applied search signals conditionally enable charge transfer from selected capacitors to a match line based on correspondence between stored data and the search signals. The match line is subsequently placed in a floating condition to permit charge redistribution, and a match or mismatch condition is determined based on a charge-related characteristic of the match line rather than on current magnitude through the ferroelectric field-effect transistors.

### DETAILED DESCRIPTION

Throughout the drawings, reference numbers are re-used to indicate correspondence between referenced elements. The drawings are provided to illustrate embodiments of the subject matter described herein and not to limit the scope thereof.

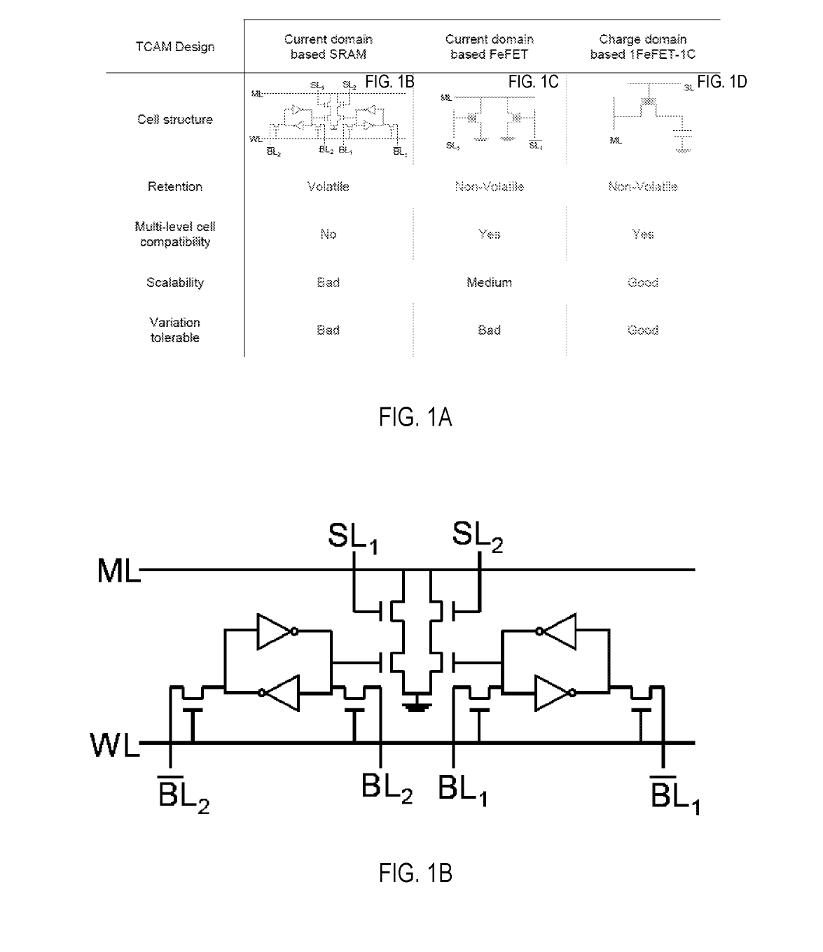

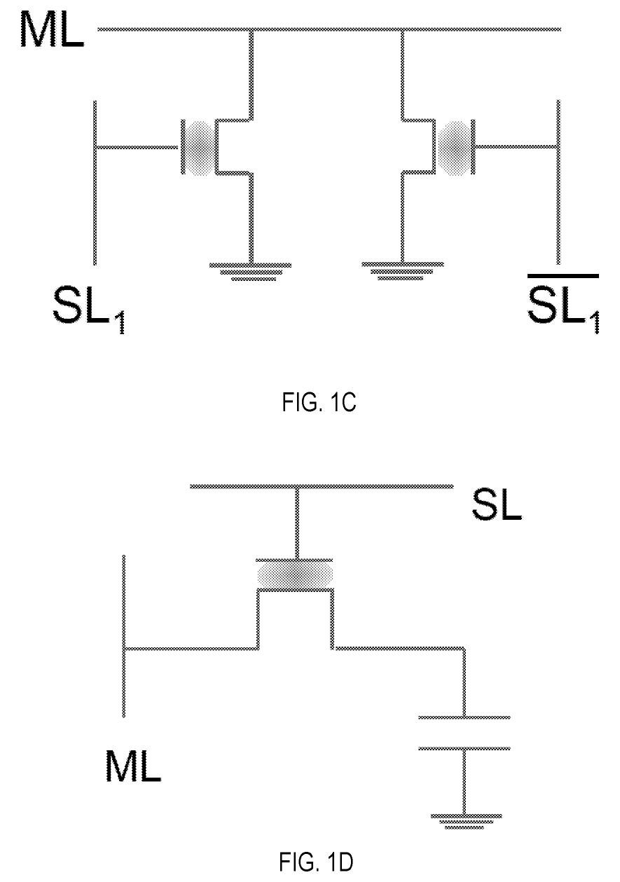

FIG. 1A illustrates a comparison of example TCAM architectures, including a current-domain SRAM-based TCAM, a current-domain FeFET-based TCAM, and a charge-domain FeFET-based TCAM.

FIG. 1B illustrates an example circuit arrangement associated with a current-domain SRAM-based TCAM cell.

FIG. 1C illustrates an example circuit arrangement associated with a current-domain FeFET-based TCAM cell.

FIG. 1D illustrates an example circuit arrangement associated with a charge-domain FeFET-based TCAM cell, in which a programmable switching device is coupled to a capacitor and a match line to enable charge-based evaluation during a search operation.

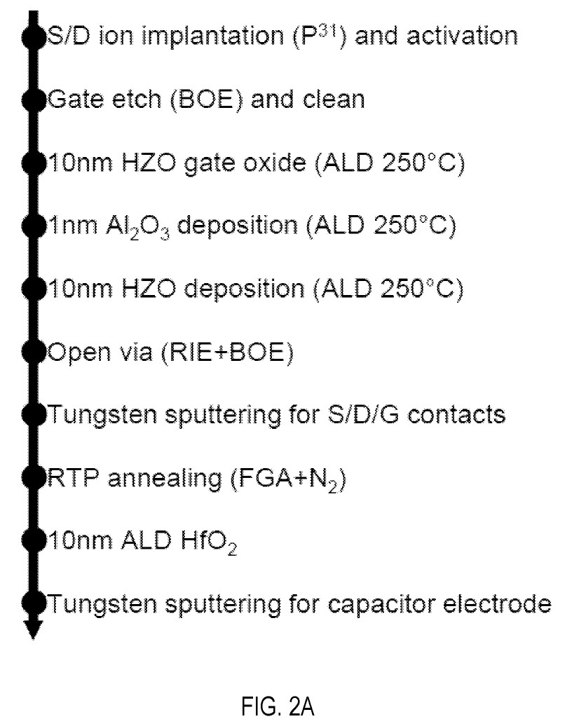

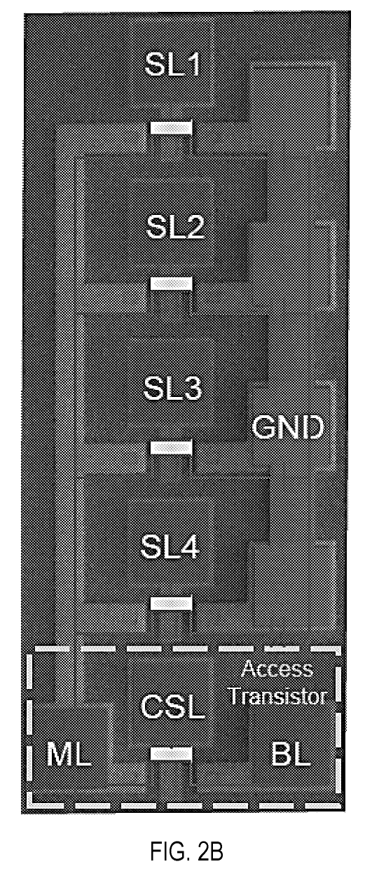

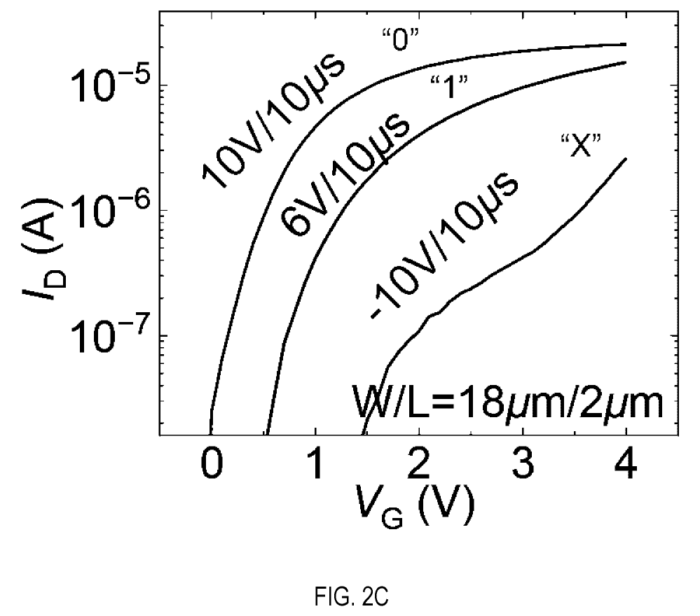

FIG. 2A–2C illustrate an example fabrication process, physical implementation, and electrical characteristics of an example ternary content-addressable memory (TCAM) cell and array, according to some aspects of the inventive concepts.

FIG. 2A illustrates an example fabrication process for forming a ferroelectric field-effect transistor (FeFET) and an associated capacitor structure.

FIG. 2B shows a scanning electron microscopy (SEM) image of an example fabricated 4×1 TCAM array that includes a plurality of memory cells and a single access transistor.

FIG. 2C illustrates example electrical characteristics of a FeFET fabricated using the process of FIG. 2A.

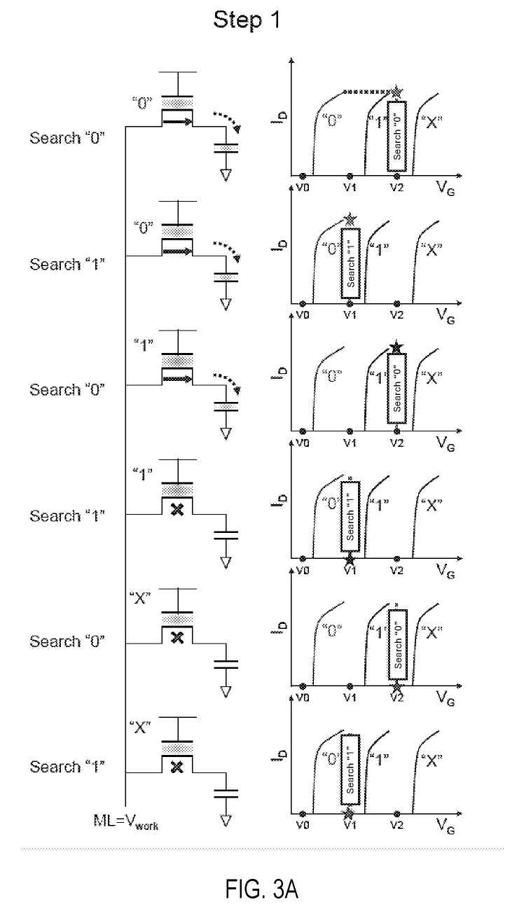

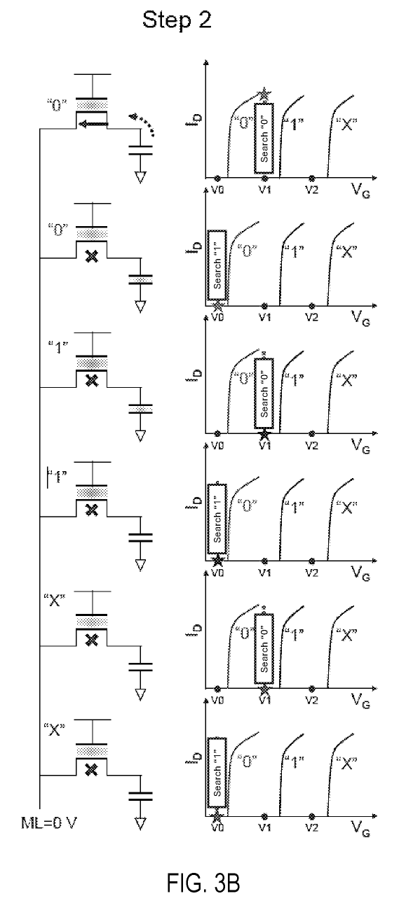

FIG. 3A illustrates an example step of a charge operation.

FIG. 3B illustrates an example step of a charge operation.

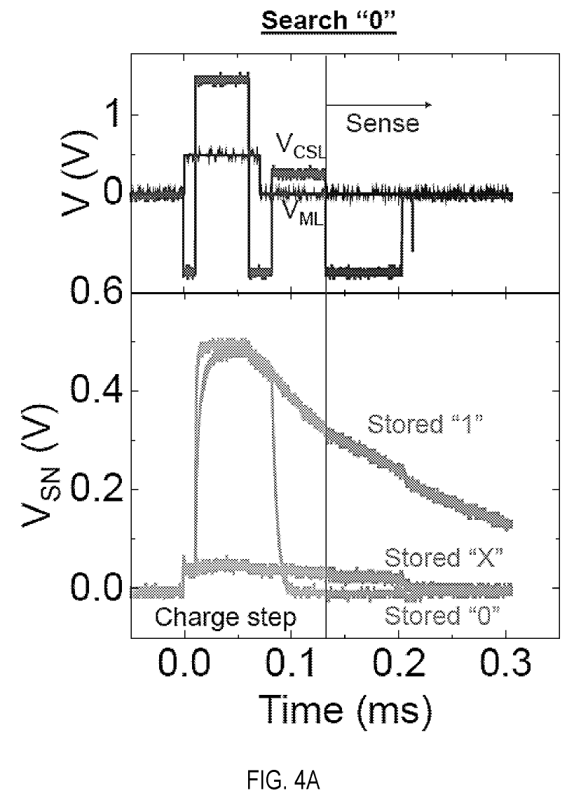

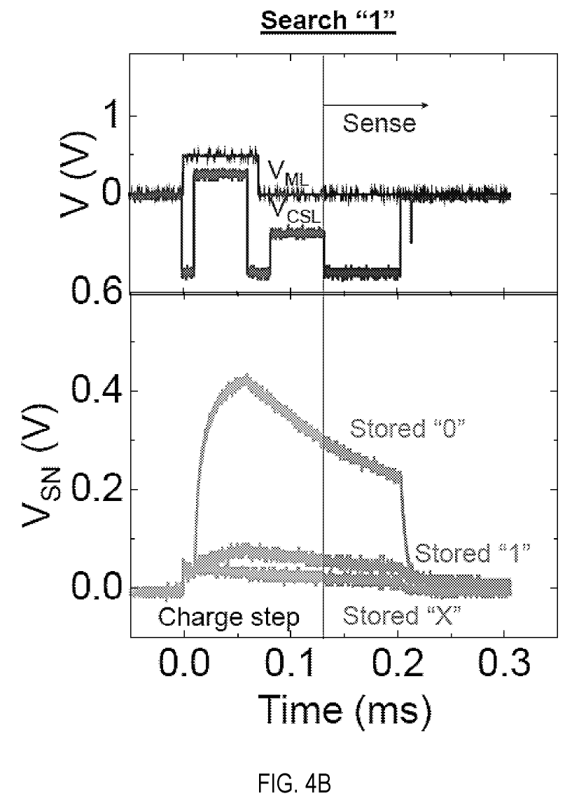

FIG. 4A illustrates example output waveforms of a sense node voltage (VSN) during a search “0” operation for a single 1FeFET-1C TCAM memory cell.

FIG. 4B illustrates example output waveforms during a search “1” operation for the same memory cell.

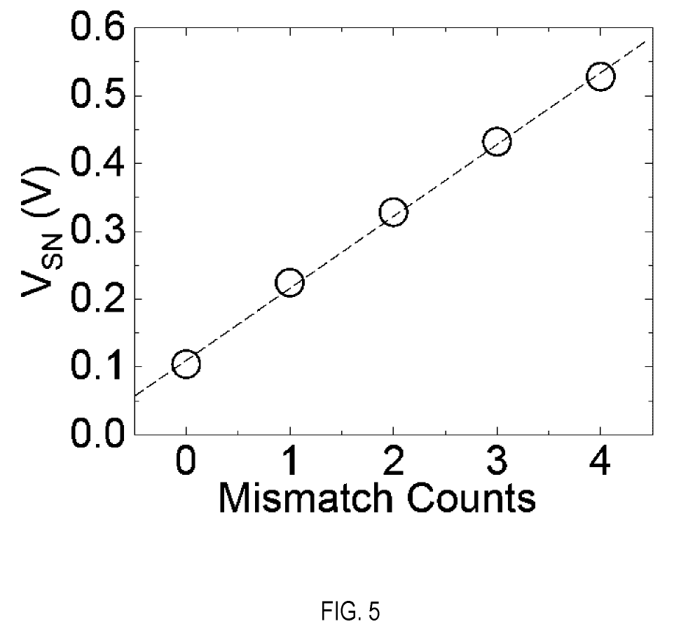

FIG. 5 illustrates example sensing results for a 4×1 1FeFET-1C TCAM array including a single access transistor.

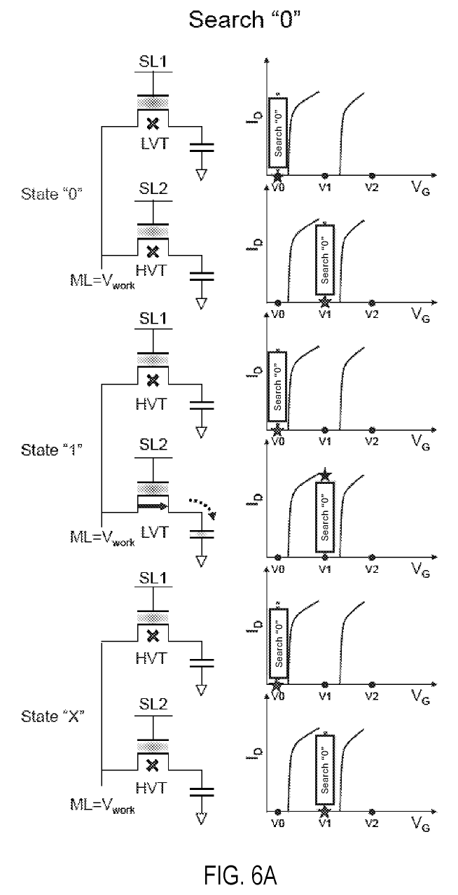

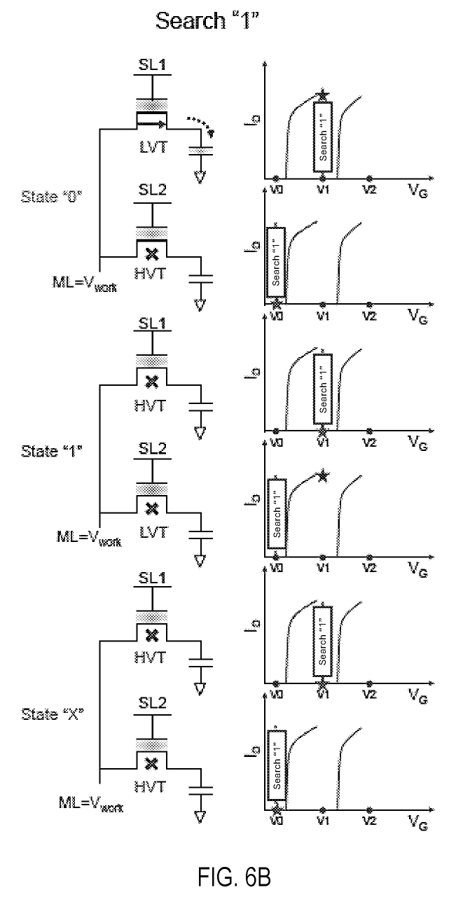

FIG. 6A illustrates example operation of the 2FeFET-2C TCAM during a search “0” operation.

FIG. 6B illustrates example operation of the 2FeFET-2C TCAM during a search “1” operation.

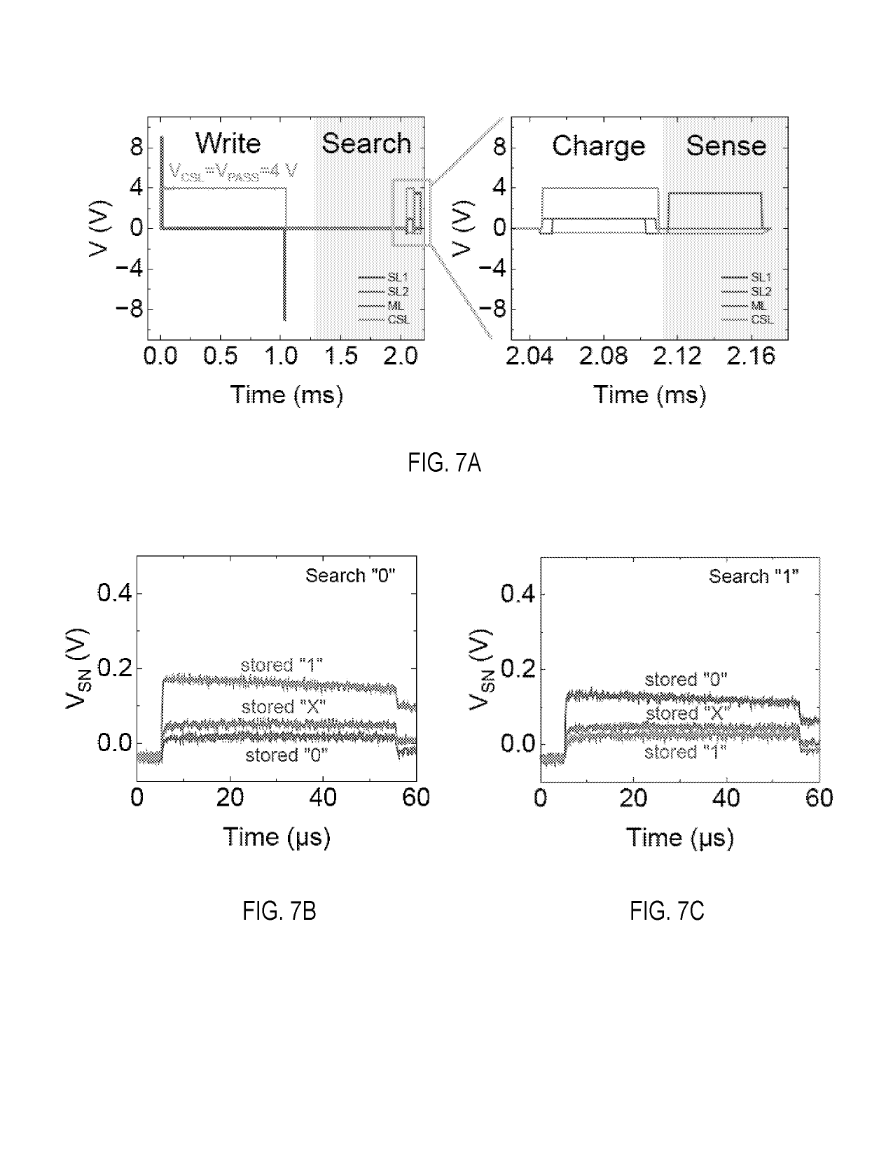

FIG. 7A illustrates an example timing waveform for write, search, charge, and sense operations of the 2FeFET-2C TCAM.

FIG. 7B illustrates example output waveforms of a sense node voltage (VSN) during a search “0” operation for memory cells storing logic “0,” “1,” and “X” states.

FIG. 7C illustrates corresponding output waveforms during a search “1” operation.

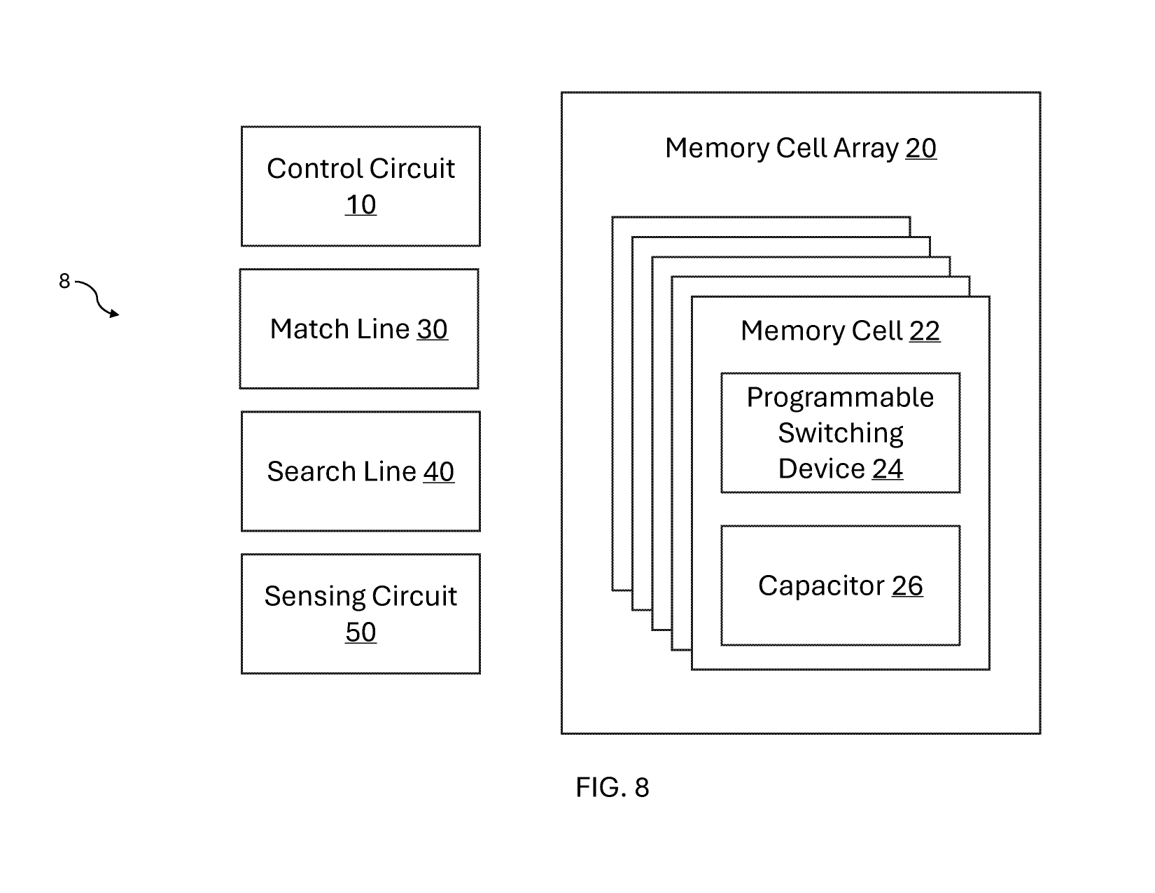

FIG. 8 illustrates a schematic block diagram of an example content-addressable memory (CAM) system 8 in accordance with the present disclosure.

### DETAILED DESCRIPTION

### OVERVIEW

In light of the description provided herein, it will be understood that the embodiments disclosed provide improvements to computer functionality in the areas of parallel search, associative lookup, and content-addressable memory operations. Conventional ternary content-addressable memory (TCAM) architectures often evaluate match conditions using current-domain sensing in which multiple memory cells contribute currents that are summed, compared, or otherwise interpreted to determine match or mismatch. Such current-domain approaches can be sensitive to device variability and operating conditions, particularly when programmable switching devices exhibit variation in ON-state current. By contrast, some inventive aspects described herein implement charge-domain techniques in which programmable switching devices operate as gating elements to conditionally enable charge transfer between capacitors and a match line based on stored states and applied search signals, after which the match line is intentionally placed in a floating condition to permit charge redistribution. A sensing circuit determines match or mismatch based on a charge-related characteristic of the match line resulting from the charge redistribution, independent of a magnitude of current conducted by the programmable switching devices.

For example, some embodiments perform a multi-step charge operation in which a match line is driven to a working voltage during a first step and driven to a reference potential during a second step, while search signals applied to control terminals of programmable switching devices selectively charge and/or discharge capacitors in memory cells as a function of stored ternary states and the applied query. After completion of the charge operation, the match line is floated to allow charge sharing between cell capacitors and parasitic capacitance associated with the match line, producing a measurable analog voltage level that represents a match condition, a mismatch condition, or a degree of mismatch. The resulting charge-domain evaluation is not dependent on summation or comparison of drain currents and is robust to variations in ON-current provided that charge transfer is enabled or disabled as intended.

Some inventive aspects described herein enhance the functioning of computing systems by enabling content-addressable search operations in which match line evaluation is performed using charge-domain sensing and intentional charge redistribution. In certain embodiments, programmable switching devices are ferroelectric field-effect transistors (FeFETs) programmed to distinct threshold voltage windows representing ternary states, and search voltages are selected relative to those threshold voltage windows to control conditional charge transfer. This approach supports parallel search across an array of memory cells while producing match line signals that can be sensed as voltage, charge, or charge-derived signals, enabling fast and scalable associative lookup operations.

Some inventive aspects described herein improve memory architectures by supporting multiple cell configurations that implement charge-domain sensing. In some configurations, a one ferroelectric field-effect transistor one capacitor (1FeFET-1C) TCAM architecture utilizes a single FeFET and a single capacitor per cell, with a multi-step charge and discharge sequence that leaves charge on capacitors associated with mismatching cells prior to match line floating and sensing. In some configurations, a two ferroelectric field-effect transistor two capacitor (2FeFET-2C) TCAM architecture utilizes two FeFETs and two capacitors per cell, with ternary states represented by combinations of threshold voltage states and with a single-step charge sequence that selectively charges one capacitor depending on a mismatch condition. These configurations provide flexible implementations that can be selected based on device programming capability, scaling constraints, and integration targets.

Some inventive aspects described herein improve match evaluation by enabling quantitative determination of mismatch information, including in some embodiments an analog indication of mismatch count or Hamming distance. For example, charge contributions from multiple mismatching memory cells can cumulatively produce a measurable match line voltage level that varies with a number of mismatching cells, enabling degree-of-mismatch outputs in addition to binary match/mismatch results. Such outputs can support computing applications that benefit from similarity search, nearest-neighbor selection, approximate matching, or other associative computing operations.

Some inventive aspects described herein therefore address technical problems in charge-based match line evaluation, variation-tolerant content-addressable search, and scalable TCAM operation using non-volatile programmable switching devices. The techniques described include conditional charge transfer controlled by stored threshold states and applied search signals, intentional match line floating to permit charge redistribution, charge-domain sensing independent of current magnitude, and implementation options using 1FeFET-1C and 2FeFET-2C memory cell structures. These capabilities materially improve the functioning of memory and computing systems that perform parallel associative searches and provide technical solutions that are not achievable using conventional current-domain TCAM sensing alone.

Some inventive aspects described herein relate to determining match, mismatch, and degree-of-mismatch conditions in a content-addressable memory array by controlling charge storage in cell capacitors during a search operation, floating a match line to permit intentional charge sharing, and sensing a resulting charge-related characteristic of the match line to generate search results, including in embodiments supporting ternary storage states and non-volatile programmable switching devices such as FeFETs.

### INTRODUCTION

Ternary Content Addressable Memory (TCAM) is used in a variety of applications, including IP address lookup, pattern matching, cache control in processors, and network intrusion detection. TCAM can facilitate parallel comparison between stored data and a search input, allowing match results to be produced with low latency. TCAM architectures typically include memory cells coupled to search lines and match lines, along with sensing circuitry configured to evaluate match conditions.

Some TCAM implementations are based on static random-access memory (SRAM) cells, which are volatile and rely on current-based sensing during search operations. Other TCAM implementations incorporate non-volatile memory elements, including ferroelectric field-effect transistors (FeFETs), which store data using programmable threshold voltage states. FeFET-based TCAM architectures may provide reduced standby power consumption and support multi-level storage relative to SRAM-based implementations.

In TCAM architectures that rely on current-domain sensing, match or mismatch conditions are determined based on current conducted through memory cells or along match lines in response to applied search signals. In such architectures, the sensed current can vary with operating voltage and device characteristics. Some TCAM architectures instead employ charge-domain sensing, in which memory cells conditionally transfer charge to a match line during a search operation and the match line is subsequently evaluated based on a charge-related characteristic.

FIG. 1A illustrates a comparison of example TCAM architectures, including a current-domain SRAM-based TCAM, a current-domain FeFET-based TCAM, and a charge-domain FeFET-based TCAM. As shown, the charge-domain FeFET-based TCAM supports non-volatile operation, multi-level cell compatibility, and scalability characteristics distinct from current-domain approaches. FIG. 1B illustrates an example circuit arrangement associated with a current-domain SRAM-based TCAM cell. FIG. 1C illustrates an example circuit arrangement associated with a current-domain FeFET-based TCAM cell. FIG. 1D illustrates an example circuit arrangement associated with a charge-domain FeFET-based TCAM cell, in which a programmable switching device is coupled to a capacitor and a match line to enable charge-based evaluation during a search operation.

In charge-domain TCAM architectures, programmable switching devices are operated as gating elements that selectively enable or disable charge transfer based on stored data and applied search signals. Following charge transfer, a match line may be placed in a floating condition to permit charge redistribution, and a sensing circuit may determine a match or mismatch condition based on a charge-related characteristic of the match line rather than on a magnitude of current conducted through the memory cells.

Some charge-domain TCAM architectures utilize memory cell configurations that include one ferroelectric field-effect transistor and one capacitor (1FeFET-1C), or two ferroelectric field-effect transistors and two capacitors (2FeFET-2C). Such configurations support ternary data storage and charge-domain sensing while maintaining compatibility with circuit structures similar to dynamic random-access memory (DRAM), including structures suitable for high-density or three-dimensional integration.

### Example Fabrication

FIGS. 2A-2C illustrate an example fabrication process, physical implementation, and electrical characteristics of an example ternary content-addressable memory (TCAM) cell and array, according to some aspects of the inventive concepts. The structures and parameters described with reference to FIGS. 2A-2C are provided as non-limiting examples, and variations consistent with the described charge-domain operation are contemplated.

FIG. 2A illustrates an example fabrication process for forming a ferroelectric field-effect transistor (FeFET) and an associated capacitor structure. In the illustrated process, source and drain regions are formed by ion implantation and activation, followed by gate etching and cleaning. A ferroelectric gate stack is formed that includes a first hafnium zirconium oxide (HZO) layer having a thickness of approximately 10 nm, an aluminum oxide (Al₂O₃) interfacial layer having a thickness of approximately 1 nm, and a second HZO layer having a thickness of approximately 10 nm, with the layers deposited using atomic layer deposition at a temperature of approximately 250°C. In some implementations, the ferroelectric layer thickness may be in a range from approximately 5 nm to 30 nm, and/or the interfacial dielectric layer thickness may be in a range from approximately 0.5 nm to 5 nm. Ferroelectric materials may include, but are not limited to, hafnium oxide-based materials doped with zirconium, silicon, aluminum, yttrium, or other suitable dopants.

Following formation of the FeFET gate stack, vias are opened using reactive ion etching and wet etching techniques. Tungsten is deposited by sputtering to form source, drain, and gate contacts, and rapid thermal processing annealing is performed in a forming gas and nitrogen environment. A capacitor structure is subsequently formed by sputtering tungsten to form a bottom electrode, depositing a hafnium oxide dielectric layer having a thickness of approximately 10 nm, and sputtering tungsten to form a top electrode. In some implementations, the capacitor dielectric thickness may be in a range from approximately 5 nm to 50 nm. The electrode material may include, but is not limited to, tungsten, titanium nitride, tantalum nitride, or other conductive materials.

FIG. 2B shows a scanning electron microscopy (SEM) image of an example fabricated 4×1 TCAM array that includes a plurality of memory cells and a single access transistor. The array includes multiple search lines, a match line, a bit line, and a cell select line coupled to the access transistor, as illustrated. In some implementations, array dimensions, routing layouts, and access transistor configurations may be varied, including larger arrays or multi-dimensional array arrangements, while maintaining charge-domain sensing operation.

FIG. 2C illustrates example electrical characteristics of a FeFET fabricated using the process of FIG. 2A. The FeFET has a channel length of approximately 2 µm and a channel width of approximately 18 µm. In some implementations, the channel length may range from sub-micron dimensions to several microns, and the channel width may range from a few microns to tens of microns. Transfer curves are shown following application of programming pulses having different amplitudes and polarities. A low-threshold-voltage state is obtained using a programming pulse of approximately +10 V with a pulse width of approximately 10 µs, a middle-threshold-voltage state is obtained using a programming pulse of approximately +6 V with a pulse width of approximately 10 µs, and a high-threshold-voltage state is obtained using a programming pulse of approximately −10 V with a pulse width of approximately 10 µs. In some implementations, programming pulse amplitudes may range from approximately ±3 V to ±15 V, and pulse widths may range from nanoseconds to milliseconds, with different pulse parameters used to establish distinct threshold voltage states.

### EXAMPLE 1FeFET-1C TCAM DESIGN

In some one ferroelectric field-effect transistor one capacitor (1FeFET-1C) ternary content-addressable memory (TCAM) architecture, a ferroelectric field-effect transistor (FeFET) is programmable to a plurality of threshold voltage states. A low-threshold-voltage state, a middle-threshold-voltage state, and a high-threshold-voltage state correspond to a logic “0,” a logic “1,” and a “don’t care” (“X”) TCAM state, respectively. The gate of each FeFET is coupled to an independent search line (SL), and the source of each FeFET in an array is coupled to a shared match line (ML). Each memory cell further includes a capacitor electrically coupled to the FeFET. Operation of the1FeFET-1C TCAM includes a write operation, a charge operation, and a charge-sharing and sensing operation.

The write operation programs the FeFET in a memory cell or array to a selected TCAM state. Following the write operation, a two-step charge operation is performed, as illustrated in FIGS. 3A and 3B. During the two-step charge operation, a voltage applied to the match line (VML) is set to a working voltage (Vwork) during a first step and to approximately 0 V during a second step.

FIG. 3A illustrates the charge operation including a first step and a second step. During the first step, the match line is driven to the voltage Vwork, and search signals corresponding to a search value are applied to the gate of the FeFET through the search line. For a search “0” operation, V2 is applied at all search lines during the first step. V2 is between the threshold voltages for the “1” and “X” states. Thus, for the search “0” operation, capacitors in cells for the “0” and “1” states are charged during the first step. During the second step, as illustrated in FIG. 3B , V1 is applied at all search lines while the match line is driven to approximately 0 V, where V1 is between the threshold voltages for the “0” and “1” states, causing capacitors in cells for the “0” state to be discharged. After the search “0” operation, only cells in the “1” state remain charged.

For a search “1” operation, V1 and V0 are applied at the search lines in step 1 and step 2. V0 is below the threshold voltages for the “0” state. Thus, for the search “1” operation, only capacitors in cells for the “1” state are charged in step 1, and no capacitors are discharged in step 2. After the search “1” operation, only cells in the “0” state remain charged. Cells in the “X” state are not charged during either the search “0” or search “1” operation. After performing the charge sequence, the match line (ML) is floated, and the charges in the capacitors inside each cell are shared and amplified by the sense amplifier. In one implementation, the ML floating operation is realized by turning off an access transistor through biasing of a cell select line (CSL).

FIG. 3B illustrates the second step of the charge operation. During the second step, the match line is driven to approximately 0 V. For a search “0” operation, the gate voltage V1 is applied, where V1 is between the threshold voltages corresponding to the “1” and “X” states. Under this condition, charge stored on the capacitors in memory cells storing the “0” state is discharged, while charge stored on the capacitors in memory cells storing the “1” state is retained. For a search “1” operation, a gate voltage V0 is applied, where V0 is below the threshold voltage corresponding to the “0” state, such that no discharge of stored charge occurs during the second step. Memory cells storing the “X” state remain electrically isolated from the match line during both the first and second steps.

As a result of the two-step charge operation illustrated in FIGS. 3A and 3B, after completion of the second step, charge remains only on the capacitors associated with memory cells whose stored TCAM states correspond to a mismatch with the applied search value. Memory cells storing matching states or the “X” state do not contribute charge. After completion of the charge operation, the match line is placed in a floating condition, and charge sharing occurs between the capacitors of the memory cells and the match line. In one implementation, the match line is floated by turning off an access transistor through biasing of a cell select line (CSL), and the resulting voltage is evaluated by a sense amplifier.

FIG. 4A illustrates output waveforms of a sense node voltage (VSN) during a search “0” operation for a single 1FeFET-1C TCAM memory cell, and FIG. 4B illustrates output waveforms during a search “1” operation for the same memory cell. Based on transfer curves corresponding to the three threshold voltage states as illustrated in FIG. 2C, the voltages V0, V1, V2, and Vwork are selected as approximately −0.5 V, 0.6 V, 1.1 V, and 0.5 V, respectively. After writing different TCAM states to the memory cell and performing the two-step charge operation shown in FIGS. 3A and 3B, the access transistor is turned off to initiate the sensing operation. During the sensing operation, the voltage of the sense node (VSN) or the match line (VML) is monitored. When the stored TCAM state mismatches the applied search value, the sense node voltage rises to a higher level of approximately 0.3 V. When the stored TCAM state matches the applied search value, the sense node voltage remains at a lower level of approximately 50 mV, resulting in a sense margin of approximately six.

FIG. 5 illustrates sensing results for a 4×1 1FeFET-1C TCAM array including a single access transistor. In this example, the initial stored state of the array is set to “0000,” and search operations are performed using search values “0001,” “0011,” “0111,” and “1111.” After performing the two-step charge operation and floating the match line, charge sharing occurs among the capacitors associated with mismatching memory cells. The resulting match line voltage (VML) is sensed, and the sensed voltage exhibits an approximately linear relationship with the number of mismatching bits. This behavior corresponds to detection of the Hamming distance between the stored data and the applied search data.

### EXAMPLE 2FeFET-2C TCAM DESIGN

Another charge-domain sensing-based ternary content-addressable memory (TCAM) architecture employs a two ferroelectric field-effect transistor two capacitor (2FeFET-2C) memory cell. In contrast to the 1FeFET-1C architecture, the 2FeFET-2C architecture uses two ferroelectric polarization states per FeFET. This configuration is applicable in implementations where multi-level threshold voltage programming of a single FeFET is limited, for example due to scaling of a ferroelectric gate stack in which a memory window is related to ferroelectric layer thickness. An example operation principle of the 2FeFET-2C TCAM is illustrated in FIGS. 6A and 6B. In this architecture, a single charge operation step is used during a search operation.

In the 2FeFET-2C memory cell, each cell includes two FeFETs and two capacitors. A combination of threshold voltage states of the two FeFETs defines a stored TCAM state. A low-threshold-voltage and high-threshold-voltage (LVT-HVT) combination defines a logic “0” state, a high-threshold-voltage and low-threshold-voltage (HVT-LVT) combination defines a logic “1” state, and a high-threshold-voltage and high-threshold-voltage (HVT-HVT) combination defines a “don’t care” (“X”) state.

FIG. 6A illustrates example operation of the 2FeFET-2C TCAM during a search “0” operation. During this operation, a first search voltage V0 is applied to a first search line (SL1), a second search voltage V1 is applied to a second search line (SL2), and a working voltage Vwork is applied to the match line (ML). Under these conditions, charge transfer from the match line is enabled only through the FeFET associated with the second capacitor in memory cells storing the logic “1” state, resulting in charging of only the second capacitor in those cells. Thus, only the second capacitor is charged in the state “1” cell. Memory cells storing the logic “0” or “X” state do not store charge during the search “0” operation.

FIG. 6B illustrates operation of the 2FeFET-2C TCAM during a search “1” operation. During this operation, the voltage V1 is applied to SL1, the voltage V0 is applied to SL2, and the working voltage Vwork is applied to the match line. Under these conditions, charge transfer from the match line is enabled only through the FeFET associated with the first capacitor in memory cells storing the logic “0” state, resulting in charging of only the first capacitor in those cells. Memory cells storing the logic “1” or “X” state do not store charge during the search “1” operation.

As a result of the single-step charge operation illustrated in FIGS. 6A and 6B, charge is stored only on capacitors associated with memory cells whose stored TCAM states correspond to a mismatch with an applied search value. Memory cells storing matching states or the “X” state do not contribute charge. Following the charge operation, the match line is placed in a floating condition to permit charge sharing between the capacitors and the match line during a subsequent sensing operation.

FIG. 7A illustrates an example timing waveform for write, search, charge, and sense operations of the 2FeFET-2C TCAM. In one implementation, a cell select line (CSL) is biased to enable writing, and the match line working voltage Vwork is set to approximately 1 V. The charge operation includes a single charge step, after which the match line is floated by turning off an access transistor prior to sensing.

FIG. 7B illustrates output waveforms of a sense node voltage (VSN) during a search “0” operation for memory cells storing logic “0,” “1,” and “X” states, and FIG. 7C illustrates corresponding output waveforms during a search “1” operation. During the sensing interval, memory cells whose stored TCAM states correspond to a mismatch with the applied search value retain charge on their associated capacitors during the charge operation and therefore contribute charge to the match line during the subsequent charge-sharing phase. As a result, when one or more memory cells store a mismatching TCAM state, the sense node voltage rises to a higher level, for example approximately 150 mV. When the stored TCAM states correspond to a match with the applied search value, little or no charge is contributed to the match line, and the sense node voltage remains at a lower level, for example approximately 50 mV. These sensing results verify correct operation of the 2FeFET-2C TCAM architecture using charge-domain match evaluation.

FIG. 8 illustrates a schematic block diagram of an example content-addressable memory (CAM) system 8 in accordance with the present disclosure. The CAM system 8 can include a control circuit 10, a memory cell array 20, one or more search lines 40, a match line 30, and a sensing circuit 50. As shown, the memory cell array 20 includes a plurality of memory cells 22. Each memory cell 22 can include a programmable switching device 24 and at least one capacitor 26 electrically coupled to the programmable switching device 24. The programmable switching device 24 can store a stored state selected from a plurality of stored states, and can be controlled by search signals applied via the one or more search lines 40 to perform content-addressable search operations.

The one or more search lines 40 can be operably coupled to control terminals of the programmable switching devices 24 in the memory cells 22 and can be configured to apply search signals representing a query. The match line 30 can be electrically coupled to the plurality of memory cells 22 such that, during a search operation, charge transfer between the capacitors 26 and the match line 30 is conditionally enabled based on both (i) stored states of the programmable switching devices 24 and (ii) the applied search signals. In some implementations, the programmable switching devices 24 operate during the search operation as gating elements that selectively enable or disable charge transfer between the capacitors 26 and the match line 30 without requiring a determination based on a magnitude of current conducted through the programmable switching devices 24.

The control circuit 10 can be configured to control one or more phases of a search operation. For example, the control circuit 10 can apply or coordinate application of the search signals on the one or more search lines 40 during a charge-transfer interval in which selected memory cells 22 conditionally transfer charge between their capacitors 26 and the match line 30. Following the charge-transfer interval, the control circuit 10 can place the match line 30 in a floating condition (e.g., by electrically isolating the match line 30 from one or more voltage sources and/or reference potentials for a period of time) to permit charge redistribution associated with the memory cells 22, such as charge sharing between the capacitors 26 and a capacitance associated with the match line 30 (including, for example, parasitic capacitance).

The sensing circuit 50 can be operably coupled to the match line 30 and can be configured to determine a correspondence between stored data and the query based on a charge-related characteristic of the match line 30 resulting from the charge redistribution while the match line 30 is in the floating condition. The charge-related characteristic can include, for example, a voltage level, a charge level, and/or a charge-derived signal on the match line 30. In some implementations, the sensing circuit 50 determines match, mismatch, or a degree of mismatch (e.g., mismatch count or Hamming distance) based on the charge-related characteristic, and the determination is performed independently of a magnitude of current conducted by the programmable switching devices 24 during the search operation (for example, without summation or comparison of drain currents from the programmable switching devices 24).

Although FIG. 8 illustrates a single search line 40 and a single match line 30 for clarity, it will be appreciated that the CAM system 8 can include multiple search lines 40 (e.g., associated with different bits, columns, or control groupings) and one or more match lines 30 (e.g., segmented, hierarchical, or per-row match lines) depending on the array organization and implementation. Further, the programmable switching device 24 can be implemented using any suitable device technology configured to support a plurality of stored states, including non-volatile devices exhibiting programmable threshold or switching characteristics. In some embodiments, the plurality of stored states can include ternary states representing logic “0,” logic “1,” and a “don’t care” state, where memory cells in the “don’t care” state can be configured to not contribute charge to the match line 30 during at least some search operations.

In some embodiments, a method for performing content-addressable memory operations is carried out using the content-addressable memory (CAM) system 8 described with reference to FIG. 8. The method includes storing data in a plurality of memory cells 22 of the memory cell array 20, wherein each memory cell 22 comprises a programmable switching device 24 and at least one capacitor 26. The programmable switching devices 24 are programmed to respective stored states selected from a plurality of stored states to represent stored data.

The method may include applying search signals representing a query to control terminals of the programmable switching devices 24 via one or more search lines 40. During a search operation, the applied search signals and the stored states of the programmable switching devices 24 conditionally control operation of the memory cells 22 such that charge transfer between the capacitors 26 and the match line 30 is selectively enabled based on correspondence between the stored data and the applied search signals.

Following the charge transfer, the method may include placing the match line 30 in a floating condition. In some implementations, placing the match line 30 in the floating condition comprises electrically isolating the match line 30 from one or more voltage sources and reference potentials for a predetermined interval. While the match line 30 is in the floating condition, intentional charge redistribution occurs, including charge sharing between the capacitors 26 of the memory cells 22 and a capacitance associated with the match line 30, such as parasitic capacitance.

The method may include determining a correspondence between the stored data and the query based on a charge-related characteristic of the match line 30 resulting from the charge redistribution. The charge-related characteristic can include a voltage level, a charge level, or a charge-derived signal on the match line 30. In some embodiments, the determination is performed independently of a magnitude of current conducted by the programmable switching devices 24 during the search operation, and does not rely on summation or comparison of drain currents.

In some embodiments, the method is performed such that charge is transferred to the match line 30 only by memory cells 22 storing data that mismatches the applied search signals, while memory cells storing matching data do not transfer charge to the match line 30 during the search operation. In such embodiments, the charge-related characteristic of the match line 30 can indicate a degree of mismatch between the stored data and the query, including, for example, an analog indication corresponding to a number of mismatching memory cells.

Although the method is described with reference to the CAM system 8 of FIG. 8, it will be understood that the described method steps can be implemented using other content-addressable memory architectures consistent with the principles disclosed herein. Further, the method steps can be performed in various sequences, can be combined, or can be repeated for successive search operations without departing from the scope of the present disclosure..

### Terminology

Computer programs typically comprise one or more instructions set at various times in various memory devices of a computing device, which, when read and executed by at least one processor, will cause a computing device to execute functions involving the disclosed techniques. In some embodiments, a carrier containing the aforementioned computer program product is provided. The carrier is one of an electronic signal, an optical signal, a radio signal, or a non-transitory computer-readable storage medium.

Any or all of the features and functions described above can be combined with each other, except to the extent it may be otherwise stated above or to the extent that any such embodiments may be incompatible by virtue of their function or structure, as will be apparent to persons of ordinary skill in the art. Unless contrary to physical possibility, it is envisioned that (i) the methods/steps described herein may be performed in any sequence and/or in any combination, and (ii) the components of respective embodiments may be combined in any manner.

Although the subject matter has been described in language specific to structural features and/or acts, it is to be understood that the subject matter defined in the appended claims is not necessarily limited to the specific features or acts described above. Rather, the specific features and acts described above are disclosed as examples of implementing the claims, and other equivalent features and acts are intended to be within the scope of the claims.

Conditional language, such as, among others, “can,” “could,” “might,” or “may,” unless specifically stated otherwise, or otherwise understood within the context as used, is generally intended to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without user input or prompting, whether these features, elements and/or steps are included or are to be performed in any particular embodiment.

Unless the context clearly requires otherwise, throughout the description and the claims, the words “comprise,” “comprising,” and the like are to be construed in an inclusive sense, as opposed to an exclusive or exhaustive sense, e.g., in the sense of “including, but not limited to.” As used herein, the terms “connected,” “coupled,” or any variant thereof means any connection or coupling, either direct or indirect, between two or more elements; the coupling or connection between the elements can be physical, logical, or a combination thereof. Additionally, the words “herein,” “above,” “below,” and words of similar import, when used in this application, refer to this application as a whole and not to any particular portions of this application. Where the context permits, words using the singular or plural number may also include the plural or singular number respectively. The word “or” in reference to a list of two or more items, covers all of the following interpretations of the word: any one of the items in the list, all of the items in the list, and any combination of the items in the list. Likewise the term “and/or” in reference to a list of two or more items, covers all of the following interpretations of the word: any one of the items in the list, all of the items in the list, and any combination of the items in the list.

Conjunctive language such as the phrase “at least one of X, Y and Z,” unless specifically stated otherwise, is otherwise understood with the context as used in general to convey that an item, term, etc. may be either X, Y or Z, or any combination thereof. Thus, such conjunctive language is not generally intended to imply that certain embodiments require at least one of X, at least one of Y and at least one of Z to each be present. Further, use of the phrase “at least one of X, Y or Z” as used in general is to convey that an item, term, etc. may be either X, Y or Z, or any combination thereof.

In some embodiments, certain operations, acts, events, or functions of any of the algorithms described herein can be performed in a different sequence, can be added, merged, or left out altogether (e.g., not all are necessary for the practice of the algorithms). In certain embodiments, operations, acts, functions, or events can be performed concurrently, e.g., through multi-threaded processing, interrupt processing, or multiple processors or processor cores or on other parallel architectures, rather than sequentially.

Systems and modules described herein may comprise software, firmware, hardware, or any combination(s) of software, firmware, or hardware suitable for the purposes described. Software and other modules may reside and execute on servers, workstations, personal computers, computerized tablets, PDAs, and other computing devices suitable for the purposes described herein. Software and other modules may be accessible via local computer memory, via a network, via a browser, or via other means suitable for the purposes described herein. Data structures described herein may comprise computer files, variables, programming arrays, programming structures, or any electronic information storage schemes or methods, or any combinations thereof, suitable for the purposes described herein. User interface elements described herein may comprise elements from graphical user interfaces, interactive voice response, command line interfaces, and other suitable interfaces.

Embodiments are also described above with reference to flow chart illustrations and/or block diagrams of methods, apparatus (systems) and computer program products. Each block of the flow chart illustrations and/or block diagrams, and combinations of blocks in the flow chart illustrations and/or block diagrams, may be implemented by computer program instructions. Such instructions may be provided to a processor of a general purpose computer, special purpose computer, specially-equipped computer (e.g., comprising a high-performance database server, a graphics subsystem, etc.) or other programmable data processing apparatus to produce a machine, such that the instructions, which execute via the processor(s) of the computer or other programmable data processing apparatus, create means for implementing the acts specified in the flow chart and/or block diagram block or blocks. These computer program instructions may also be stored in a non-transitory computer-readable memory that can direct a computer or other programmable data processing apparatus to operate in a particular manner, such that the instructions stored in the computer-readable memory produce an article of manufacture including instruction means which implement the acts specified in the flow chart and/or block diagram block or blocks. The computer program instructions may also be loaded to a computing device or other programmable data processing apparatus to cause operations to be performed on the computing device or other programmable apparatus to produce a computer implemented process such that the instructions which execute on the computing device or other programmable apparatus provide steps for implementing the acts specified in the flow chart and/or block diagram block or blocks.

Any patents and applications and other references noted above, including any that may be listed in accompanying filing papers, are incorporated herein by reference. Aspects of the invention can be modified, if necessary, to employ the systems, functions, and concepts of the various references described above to provide yet further implementations of the invention. These and other changes can be made to the invention in light of the above Detailed Description. While the above description describes certain examples of the invention, and describes the best mode contemplated, no matter how detailed the above appears in text, the invention can be practiced in many ways. Details of the system may vary considerably in its specific implementation, while still being encompassed by the invention disclosed herein. As noted above, particular terminology used when describing certain features or aspects of the invention should not be taken to imply that the terminology is being redefined herein to be restricted to any specific characteristics, features, or aspects of the invention with which that terminology is associated. In general, the terms used in the following claims should not be construed to limit the invention to the specific examples disclosed in the specification, unless the above Detailed Description section explicitly defines such terms. Accordingly, the actual scope of the invention encompasses not only the disclosed examples, but also all equivalent ways of practicing or implementing the invention under the claims.

To reduce the number of claims, certain aspects of the invention are presented below in certain claim forms, but the applicant contemplates other aspects of the invention in any number of claim forms. Any claims intended to be treated under 35 U.S.C. §112(f) will begin with the words “means for,” but use of the term “for” in any other context is not intended to invoke treatment under 35 U.S.C. §112(f). Accordingly, the applicant reserves the right to pursue additional claims after filing this application, in either this application or in a continuing application.

What is claimed is:

1. A content-addressable memory system, comprising:
a memory cell array including a plurality of memory cells, each memory cell comprising:
a programmable switching device having a stored state selected from a plurality of stored states; and
at least one capacitor electrically coupled to the programmable switching device;
one or more search lines operably coupled to control terminals of the programmable switching devices and configured to apply search signals representing a query;
a match line electrically coupled to the memory cells;
a control circuit configured to:
apply the search signals to the programmable switching devices such that, during a search operation, charge transfer between the capacitors and the match line is conditionally enabled based on both the stored states and the applied search signals; and
place the match line in a floating condition following the charge transfer to permit intentional charge redistribution associated with the memory cells; and
a sensing circuit operably coupled to the match line and configured to determine a correspondence between stored data and the query based on a charge-related characteristic of the match line resulting from the intentional charge redistribution, the determination being independent of a magnitude of current conducted by the programmable switching devices during the search operation.

2. The content-addressable memory system of claim 1, wherein the sensing circuit is configured to determine the correspondence between the stored data and the query based on a voltage, charge, or charge-derived signal on the match line.

3. The content-addressable memory system of claim 1, wherein the sensing circuit does not perform summation or comparison of drain currents from the programmable switching devices during the search operation.

4. The content-addressable memory system of claim 1, wherein each programmable switching device is operated during the search operation as a binary gating element that selectively enables or disables charge transfer, independent of variations in an ON-state current of the programmable switching device.

5. The content-addressable memory system of claim 1, wherein placing the match line in the floating condition comprises electrically isolating the match line from a voltage source and a reference potential for a predetermined time interval following the charge transfer, wherein the intentional charge redistribution comprises charge sharing among the at least one capacitor of each memory cell and a parasitic capacitance associated with the match line.

6. The content-addressable memory system of claim 1, wherein the at least one capacitor of each memory cell is a deliberately formed capacitor structure configured to store charge representative of a match or mismatch condition during the search operation, wherein the capacitor is dimensioned such that a cumulative charge contribution from multiple memory cells produces a measurable analog voltage level on the match line indicative of a number of mismatching memory cells.

7. The content-addressable memory system of claim 1, wherein the plurality of stored states comprises a first state representing a logic “0,” a second state representing a logic “1,” and a third state representing a “don’t care” state, and wherein memory cells in the don’t care state do not contribute charge to the match line during the search operation.

8. The content-addressable memory system of claim 7, wherein the control circuit applies search signals such that charge transfer is conditionally enabled only for memory cells storing a state that mismatches the query.

9. The content-addressable memory system of claim 1, wherein charge is transferred to the match line only by memory cells storing data that mismatches the applied search signals.

10. The content-addressable memory system of claim 1, wherein each programmable switching device comprises a ferroelectric field-effect transistor (FeFET) having a threshold voltage programmed to represent one of the plurality of stored states.

11. The content-addressable memory system of claim 10, wherein the plurality of stored states correspond to distinct threshold voltage windows of the FeFET, and the search signals are selected to fall between adjacent threshold voltage windows.

12. The content-addressable memory system of claim 1, wherein each memory cell comprises a single programmable switching device and a single capacitor, wherein the charge transfer includes a multi-step charge and discharge sequence controlled by the search signals, and wherein the control circuit is configured to perform a first charge step and a second discharge step prior to placing the match line in the floating condition.

13. The content-addressable memory system of claim 1, wherein each memory cell comprises two programmable switching devices and two capacitors, and wherein the plurality of stored states is encoded by a combination of threshold voltage states of the two programmable switching devices.

14. The content-addressable memory system of claim 13, wherein the charge transfer comprises a single charge step, and the intentional charge redistribution occurs following the single charge step.

15. The content-addressable memory system of claim 1, wherein the sensing circuit is configured to generate an output representing a degree of mismatch between the stored data and the query based on a magnitude of the charge-related characteristic of the match line.

16. The content-addressable memory system of claim 1, wherein the programmable switching device comprises a non-volatile device exhibiting a programmable threshold or switching characteristic independent of stored charge in the capacitor.

17. A method for performing content-addressable memory operations, comprising:
storing data in a plurality of memory cells, each memory cell comprising a programmable switching device and at least one capacitor;
applying search signals to control terminals of the programmable switching devices representing a query;
during a search operation, conditionally enabling charge transfer between the capacitors and a match line based on both stored states of the programmable switching devices and the applied search signals;
placing the match line in a floating condition following the charge transfer to permit intentional charge redistribution associated with the memory cells; and
determining a correspondence between the stored data and the query based on a charge-related characteristic of the match line resulting from the intentional charge redistribution, wherein the determining is performed independently of a magnitude of current conducted by the programmable switching devices.

18. The method of claim 17, wherein charge is transferred to the match line only by memory cells storing data that mismatches the applied search signals, wherein memory cells storing matching data do not transfer charge to the match line during the search operation, and wherein the determining comprises detecting a voltage level on the match line indicative of a number of mismatching memory cells.

19. A ternary content-addressable memory device, comprising:
a memory cell array including a plurality of memory cells, each memory cell comprising a programmable switching device configured to store data in a plurality of states and at least one capacitor;
one or more search lines coupled to the programmable switching devices;
a match line coupled to the memory cells and configured to be selectively floated; and
a sensing circuit coupled to the match line and configured to detect charge redistribution on the match line resulting from conditional charge transfer from the capacitors during a search operation,
wherein match or mismatch between stored data and applied search signals is determined based on charge-domain sensing rather than a magnitude of current through the programmable switching devices.

20. The ternary content-addressable memory device of claim 19, wherein the sensing circuit is configured to detect a voltage, charge, or charge-derived signal on the match line resulting from intentional charge sharing while the match line is in a floating condition, and does not perform summation or comparison of drain currents from the programmable switching devices during the search operation.
